(19) United States
(12) Patent Application Publication
(10) Pub. No.: US 2008/0194106 A1
(43) Pub. Date: Aug. 14, 2008

(54) METHOD OF FORMING A TITANIUM ALUMINUM NITRIDE LAYER AND METHOD OF MANUFACTURING A PHASE-CHANGE MEMORY DEVICE USING THE SAME

(75) Inventors: Gyu-Hwan OH, Gyeonggi-do (KR); In-Sun PARK, Gyeonggi-do (KR); Hyun-Seok LIM, Gyeonggi-do (KR); Nak-Hyun LIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/030,662

(22) Filed: Feb. 13, 2008

(30) Foreign Application Priority Data
Feb. 13, 2007 (KR) 2007-0014629

(51) Int. Cl. H01L 21/44

(52) U.S. Cl. 438/685; 257/E21.021

(57) ABSTRACT

In a method of forming a titanium aluminum nitride layer, a first reactant is formed on a substrate by reacting a first source including titanium and a second source including nitrogen. A second reactant is formed by providing a third source including aluminum onto the substrate having the first reactant thereon and reacting the third source with the first reactant. A third reactant is formed by providing a fourth source including nitrogen onto the substrate having the second reactant thereon and reacting the fourth source with the second reactant. The titanium aluminum nitride layer having a good step coverage is formed on the substrate. Processes of forming the titanium aluminum nitride layer are simplified and deposition rate is improved. Therefore, a phase-change memory device using the titanium aluminum nitride layer as a lower electrode may have an improved throughput.

### CROSS-REFERENCE TO RELATED APPLICATIONS

This application claims the benefit of foreign priority to Korean Patent Application No. 10-2007-14629 filed on Feb. 13, 2007, the disclosure of which is incorporated herein by reference in its entirety.

### BACKGROUND

1. Field of Invention

Example embodiments of the present invention relate to methods of forming a titanium aluminum nitride layer and methods of manufacturing phase-change memory devices using the same. More particularly, example embodiments of the present invention relate to a method of forming a titanium aluminum nitride layer and a method of manufacturing a phase-change memory device including a lower electrode having a desired specific resistance using the same.

2. Description of the Related Art

Generally, semiconductor memory devices can be classified as either volatile semiconductor memory devices (e.g., dynamic random access memory (DRAM) devices or static random access memory (SRAM) devices) or non-volatile semiconductor memory devices (e.g., flash memory devices or electrically erasable and programmable read only memory (EEPROM) devices) depending on whether data is retained when a power supply is turned off or deactivated. Among non-volatile memory devices, flash memory devices are mainly used in digital cameras, MP3 players, cell phones, etc., to retain data without the power supply.

Conventional flash memory devices require a relatively long time for writing or erasing data. Accordingly, new semiconductor memory devices such as magnetic random access memory (MRAM) devices, ferroelectric random access memory (FRAM) devices and phase-change random access memory (PRAM) devices have recently been developed to replace conventional flash memory devices.

A PRAM device stores data therein using a resistance difference between two states, i.e., a crystalline state and an amorphous state of a phase-change material layer including chalcogenide (e.g., germanium-antimony-tellurium (Ge—Sb—Te; GST)), which may be generated by a phase transition of the phase-change material layer.

A typical PRAM device includes a phase-change material layer, a lower electrode that applies current to a lower portion of the phase-change material layer and an upper electrode disposed on the phase-change material layer.

The lower electrode has conventionally been formed using a titanium aluminum nitride electrode using an atomic layer deposition (ALD) process. Methods of forming the titanium aluminum nitride layer using the ALD process are known to be disclosed in Korean Patent No.10-0604923.

In a typical ALD process for forming the titanium aluminum nitride layer, a titanium source, an aluminum source, and a nitrogen source are provided and purged, respectively.

Because many steps are carried out in the ALD process, a processing time is increased and a deposition speed is decreased during formation of the lower electrode. Thus, the throughput of PRAM devices including a lower electrode formed of titanium aluminum nitride is reduced.

Additionally, when many sources are alternately provided to a chamber during an ALD process to form the titanium aluminum nitride layer, the sources may remain in the chamber and contaminate the chamber. Furthermore, a cycle of a cleaning process for removing the remaining sources in the chamber may be shortened.

Titanium aluminum nitride layers formed by the ALD process may have a step coverage that is superior relative to the step coverage of a titanium aluminum nitride layer formed by a chemical vapor deposition (CVD) process.

FIGS. 1 and 2 are scanning electron microscope (SEM) pictures illustrating step coverage of a titanium aluminum nitride layer formed by a conventional ALD process. Specifically, FIG. 1 is a SEM picture illustrating a titanium aluminum nitride layer in a cell region of a PRAM device and FIG. 2 is a SEM picture illustrating a titanium aluminum nitride layer in a peripheral region of a PRAM device.

Referring to FIGS. 1 to 2, the titanium aluminum nitride layer formed by the conventional ALD process has a step coverage of about 75% at an opening in a cell region and a step coverage of about 77% at an opening in a peripheral region.

To form a lower electrode, an upper portion of the titanium aluminum nitride layer is removed. When the upper portion of the titanium aluminum nitride layer having a step coverage of about 75% to about 77% is removed, a seam or a void may be undesirably formed in the lower electrode.

Thus, the titanium aluminum nitride layer needs to have a step coverage superior to that in the above range. As an integration degree of a PRAM device has increased, the titanium aluminum nitride layer employed in the lower electrode needs to have a superior step coverage.

### SUMMARY

Example embodiments of the present invention provide a method of forming a titanium aluminum nitride layer having a good step coverage, a high throughput and less contamination.

Example embodiments of the present invention also provide a method of manufacturing a phase-change memory device using the method of forming the titanium aluminum nitride layer.

One example embodiment described herein can be generally characterized as a method of forming a titanium aluminum nitride layer that includes forming a first reactant on a substrate by reacting a first source including titanium and a second source including nitrogen; forming a second reactant by providing a third source including aluminum onto the substrate having the first reactant thereon and reacting the third source with the first reactant; and forming a third reactant by providing a fourth source including nitrogen onto the substrate having the second reactant thereon and reacting the fourth source with the second reactant.

Another example embodiment described herein can be generally characterized as a method of manufacturing a phase-change memory device that includes forming an insulating pattern having an opening therethrough on a substrate; forming a titanium aluminum nitride layer filling up the opening; removing an upper portion of the titanium aluminum nitride layer until the insulating pattern is exposed to form a lower electrode; and forming a phase-change material layer and an upper electrode on the lower electrode. The titanium aluminum nitride layer may be formed according to a method that includes forming a first reactant by reacting a first source including titanium and a second source including nitrogen; forming a second reactant by providing a third source including aluminum and reacting the third source with the first reactant; and forming a third reactant by providing a fourth source including nitrogen and reacting the fourth source with the second reactant.

### BRIEF DESCRIPTION OF THE DRAWINGS

The above and other features and advantages of the embodiments described herein will become more apparent by reference to the following detailed description when considered in conjunction with the accompanying drawings wherein:

FIGS. 1 and 2 are scanning electron microscope (SEM) pictures illustrating a step coverage of a titanium aluminum nitride layer formed by a conventional atomic layer deposition (ALD) process;

FIG. 3 is a flow chart illustrating a method of forming a titanium aluminum nitride layer in accordance with some example embodiments of the present invention;

FIG. 4 is a timing diagram showing times during which source gases are provided in the method of forming the titanium aluminum nitride layer with reference to FIG. 3;

FIG. 5 is a graph illustrating a relationship between an amount of aluminum incorporated within the titanium aluminum nitride layer, and a specific resistance of the titanium aluminum nitride layer, as a function of the amount of trimethylaluminum (TMA) gas used to form the second reactant;

FIGS. 6 to 12 are cross-sectional views illustrating an exemplary method of manufacturing a phase-change memory transistor using the method of forming the titanium aluminum nitride layer in FIG. 3;

FIGS. 13 and 14 are SEM pictures illustrating step coverage characteristics of a titanium aluminum nitride layer in accordance with an example embodiment of the present invention;

FIG. 15 is graphs showing X-ray diffraction (XRD) patterns of crystal structures of a titanium aluminum nitride layer formed by a conventional method and a titanium aluminum nitride layer in accordance with an example embodiment of the present invention, respectively;

FIG. 16 is graphs showing XRD patterns of the crystal structures of the titanium aluminum nitride layers in FIG. 15 after performing heat treatments;

FIG. 17 is a table showing specific resistances and amounts of aluminum of a titanium aluminum nitride layer formed by a conventional method and a titanium aluminum nitride layer in accordance with an example embodiment of the present invention, respectively, before and after performing heat treatments; and

FIG. 18 is a table showing currents, resistances, powers and energies associated with device failure of a titanium aluminum nitride layer formed by a conventional method and a titanium aluminum nitride layer formed in accordance with an example embodiment of the present invention, respectively.

### DETAILED DESCRIPTION

Example embodiments of the present invention are described more fully hereinafter with reference to the accompanying drawings. These embodiments may, however, be realized in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an exemplary method of forming a titanium aluminum nitride layer will be exemplarily described.

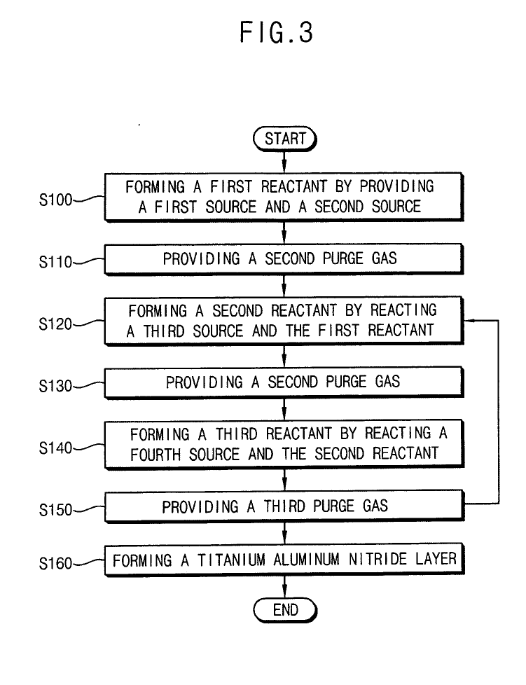

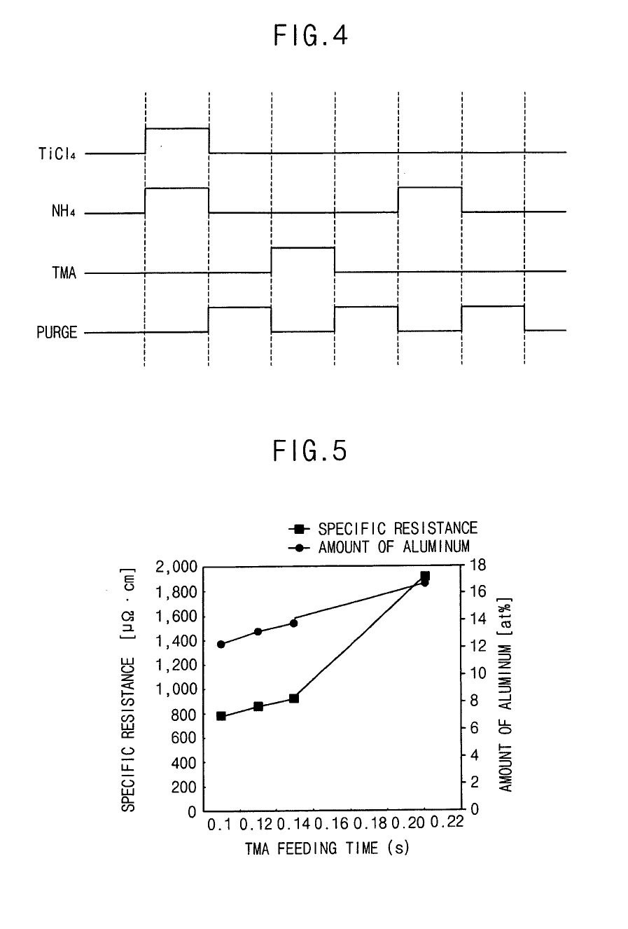

FIG. 3 is a flow chart illustrating a method of forming a titanium aluminum nitride layer in accordance with some example embodiments of the present invention. FIG. 4 is a timing diagram showing times during which source gases are provided in the method of forming the titanium aluminum nitride layer with reference to FIG. 3.

Referring to FIGS. 3 and 4, a substrate (not shown) is loaded into a chamber (not shown).

The substrate may be a silicon substrate, a germanium substrate or the like. In another embodiment, the substrate may be a silicon-on-insulator (SOI) substrate, a germanium-on-insulator (GOI) substrate or the like. The substrate may have electric circuits provided thereon.

A first source including titanium (Ti) and a second source including nitrogen (N₂) are provided into the chamber to form a first reactant on the substrate (see S100). The first reactant may include a titanium nitride layer.

The first source may include titanium tetrachloride (TiCl₄), tetrakis dimethylamino titanium (TDMAT), tetrakis diethylamino titanium (TDEAT), tetrakis ethylmethylamino titanium (TEMAT), tetra tertiary butoxy titanium (Ti(OtBu)₄) or the like. These may be used alone or in a combination thereof. The second source may include ammonia (NH₃), nitrogen oxide (NO), nitrous oxide (N₂0), nitrogen (N₂), dimethylhydrazine (DMH) or the like. These may be used alone or in a combination thereof.

In an example embodiment, the first and second sources may be a titanium tetrachloride (TiCl₄) gas and an ammonia (NH₃) gas, respectively. A flow rate ratio of the first source to the second source may be about 0.5:1 to about 10:1. In another embodiment, a flow rate ratio of the first source to the second source may be about 1:25 to about 1:45. The chamber may be maintained at a temperature of about 400° C. to about 600° C. under a pressure of about 0.7 Torr to about 5.0 Torr.

When the first and second sources are provided simultaneously, a reactant of the first and second sources (i.e., the first reactant) may be formed by a process substantially the same as a conventional chemical vapor deposition (CVD) process. However, the first and second sources may be prevented from completely reacting by maintaining a pressure and a temperature in the chamber lower than those of the conventional CVD process. Accordingly, the first reactant may include chlorine, titanium, etc., in addition to the titanium nitride layer. The first reactant may remain within the chamber.

The chlorine in the titanium nitride layer, i.e., the titanium nitride layer not having been reacted, may serve as a binding site with which aluminum provided in a successive process may be bound. Thus, a titanium aluminum nitride layer formed in the successive process may have good step coverage by the binding site.

In some embodiments, unreacted portions of the first and second sources may remain in the chamber, in addition to the first reactant. The remaining portions of the first and second sources in the chamber may be removed by a first purge gas (see S110).

The first purge gas may include an inactive gas. For example, the inactive gas includes nitrogen (N₂) gas, argon (Ar) gas, etc. These may be used alone or in a combination thereof.

A third source including aluminum (Al) is provided into the chamber. The third source is reacted with the first reactant on the substrate, thereby forming a second reactant (see S120).

The third source may, include trimethylaluminum (TMA), diethylamino alane (DEAA), dimethylamino-2-methyl propyl methyl aluminium hydride, aluminum borohydride trimethylamine, dimethyl aluminum hydride (DMAH), tri-isobutyl aluminum (TIBA) or the like. These may be used alone or in a combination thereof. For purposes of the following discussion, TMA is used as the third source.

TMA gas is provided into the chamber together with a carrier gas. The carrier gas may include an inactive gas such as nitrogen (N₂) gas, argon (Ar) gas, or the like or a combination thereof. The TMA gas may have a flow rate proportional to that of the inactive gas. Thus, the flow rate of the TMA gas may be known by the flow rate of the inactive gas. A flow rate ratio of the inactive gas to the third source may be about 5:1.

The chamber may be maintained at a temperature of about 400° C. to about 600° C. under a pressure of about 0.7 Torr to about 5.0 Torr.

In the process conditions outlined above, aluminum included in the third source is bound to the binding sites. Particularly, the first reactant has binding sites with which aluminum may be bound and aluminum in the TMA gas is bound to the binding sites. Accordingly, a second reactant may be formed on the substrate. In one embodiment, the second reactant may include titanium aluminum nitride. In other embodiments, the second reactant may also include titanium aluminum, etc., in addition to the titanium aluminum nitride.

In some embodiments, unreacted portions of the third source may remain in the chamber, in addition to the second reactant. The remaining portion of the third source may be removed by a second purge gas (see S130).

The second purge gas includes an inactive gas. For example, the inactive gas includes nitrogen (N₂) gas or argon (Ar) gas. These may be used alone or in a combination thereof. In one embodiment, the second purge gas is substantially the same as the first purge gas. In another embodiment, the second purge gas is different from the first purge gas.

A specific resistance of a titanium aluminum nitride layer formed according to the processes exemplarily described herein may be determined according to an amount of the TMA gas used to form the second reactant.

FIG. 5 is a graph illustrating a relationship between an amount of aluminum incorporated within the titanium aluminum nitride layer, and a specific resistance of the titanium aluminum nitride layer, as a function of the amount of trimethylaluminum (TMA) gas used to form the second reactant.

Referring to FIG. 5, the amount of the TMA gas used to form the second reactant may be controlled by controlling a feeding time and/or a feeding rate of the TMA gas. For example, as shown in FIG. 5, as the feeding time of the TMA gas increases, the amount of aluminum in the second reactant (and, thus, in the titanium aluminum nitride layer) increases, and thus the specific resistance of the titanium aluminum nitride layer increases. Similar effects can be observed upon increasing the feeding rate of the TMA gas.

Referring back to FIGS. 3 and 4, a fourth source including nitrogen is provided into the chamber. The fourth source is reacted with the second reactant on the substrate to form a third reactant (see S140).

The fourth source may include NH₃, NO, N₂O, N₂, dimethylhydrazine (NH₂N(CH₃)₂), or the like. These may be used alone or in a combination thereof. For purposes of the following discussion, the fourth source includes NH₃. The chamber may be maintained at a temperature of about 400° C. to about 600° C. under a pressure of about 0.7 Torr to about 5.0 Torr.

In the process conditions outlined above, the second reactant is reacted with the fourth source to form a third reactant. In one embodiment, the third reactant includes titanium aluminum nitride.

In some embodiments, unreacted portions of the fourth source may remain in the chamber, in addition to the third reactant. The remaining portion of the fourth source may be removed by a third purge gas (see S150).

The third purge gas includes an inactive gas. For example, the inactive gas includes nitrogen (N₂) gas or argon (Ar) gas. These may be used alone or in a combination thereof. In one embodiment, the third purge gas is substantially the same as the second purge gas. In another embodiment, the third purge gas is different from the second purge gas.

The specific resistance of a titanium aluminum nitride layer formed according to the method exemplarily described above may be determined according to an amount of nitrogen used to form the third reactant. The amount of the nitrogen used to form the third reactant may be controlled by controlling a feeding time and/or a feeding rate of the fourth source. For example, as the feeding time or the feeding rate of the fourth source increases, the amount of the nitrogen in the third reactant (and, thus, in the titanium aluminum nitride layer) increases, and thus the specific resistance of the titanium aluminum nitride layer increases.

The method from S120 to S150 may be repeated as necessary to form a titanium aluminum nitride layer on the substrate (see S160). Thus, a titanium aluminum nitride layer having a desirable specific resistance and a thickness may be formed upon repeating the method from S120 to S150.

In one embodiment, when the third source is provided, the chamber is maintained at a temperature of about 400° C. to about 600° C. under a pressure of about 0.7 Torr to about 5.0 Torr, and then the third purge gas is provided to form the second reactant. The fourth source is provided into the chamber, and then the fourth purge gas is provided to form the third reactant.

The specific resistance and the thickness of the titanium aluminum nitride formed. according to the processes exemplarily described herein may be determined according to the number of times the process is repeated from S120 to S150. That is, as the number of times the process from S120 to S150 is repeated, the amount of aluminum and nitrogen in the resultant titanium aluminum nitride increases. Thus, the specific resistance of the titanium aluminum nitride layer increases. Additionally, the thickness of the titanium aluminum nitride layer increases.

In some embodiments, the titanium aluminum nitride layer can be characterized by the structural formula: Ti₁₋ₓ,Alₓ,N, wherein x is more than 0 and less than about 0.3. In one embodiment, x is less than 0.3. When x is in a range of about 0 to about 0.25, the titanium aluminum nitride layer may have a specific resistance of about 600 μΩ cm to about 2,000 μΩ cm.

The method used to form the titanium aluminum nitride layer, as exemplarily described above, may be used to form titanium aluminum nitride layers faster than conventional ALD techniques. Additionally, a specific resistance of the titanium aluminum nitride layer may be controlled by controlling amounts of aluminum and nitrogen used during formation of the titanium aluminum nitride layer.

Hereinafter, a method of forming a phase-change memory device by using the above-described method of forming the titanium aluminum nitride layer will be illustrated.

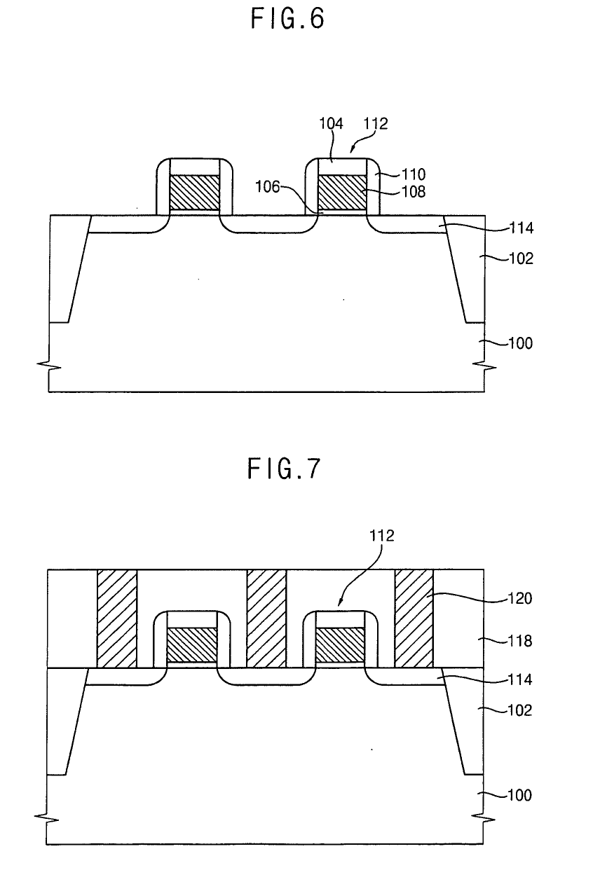

FIGS. 6 to 12 are cross-sectional views illustrating an exemplary method of manufacturing a phase-change memory transistor using the method of forming the titanium aluminum nitride layer in FIG. 3.

Referring to FIG. 6, an isolation layer pattern 102 is formed at an upper portion of a substrate 100. The isolation layer pattern 102 defines an active region in the substrate 100.

The substrate 100 may include a semiconductor substrate such as a silicon substrate, a germanium substrate, a SOI substrate, a GOI substrate or the like.

The isolation layer pattern 102 may be formed as follows. A pad oxide layer (not shown) and a mask (not shown) are formed on the substrate 100. The pad oxide layer and the substrate 100 are partially etched to form a pad oxide layer pattern (not shown) and a trench using the mask as an etching mask. An isolation layer is formed on the mask to fill up the trench. The isolation layer pattern 102 may be formed by planarizing an upper portion of the isolation layer.

In an example embodiment, an annealing process may be performed at a temperature of about 800° C. to about 1,050° C. in an inactive gas atmosphere to densify the isolation layer pattern 102. Upon being densified, the isolation layer pattern 102 can have a decreased wet-etching rate during a successive cleaning process.

A gate insulating layer (not shown), a gate conductive layer (not shown), and a nitride layer pattern 104 are formed on the substrate 100 having the isolation layer pattern 102 therein. The gate insulating layer may, for example, include an oxide formed using a CVD process or a thermal oxidation process. The gate conductive layer may, for example, include polysilicon doped with impurities or a metal formed by a CVD process or a physical vapor deposition (PVD) process.

The gate conductive layer and the gate insulating layer are partially etched using the nitride layer pattern 104 as an etching mask to form a gate insulating layer pattern 106 and a gate conductive pattern 108, respectively. Thus, a gate electrode may be formed on the substrate 100 and include the gate insulating layer pattern 106 and the gate conductive pattern 108, which are sequentially stacked. In some example embodiments, a plurality of gate electrodes are formed on the substrate 100

Ions are implanted into a portion of the substrate 100 using the gate electrodes as ion implantation masks, so that a source/drain region 114 may be formed at an upper portion of the substrate 100. Additionally, spacers 110 may be formed at sidewalls of the gate electrodes and the nitride layer patterns 104.

The source/drain region 114 may have a lightly doped drain (LDD) structure by implanting impurities onto the substrate 100 after forming the spacers 110.

A transistor 112 having the gate electrode and the source/drain region 114 may be formed on the substrate 100 having the isolation layer pattern 102 therein.

Referring to FIG. 7, a first insulating interlayer is formed on the substrate 100 to cover the transistor 112.

The first insulating interlayer may, for example, include borophosphosilicate glass (BPSG), Tonen SilaZene (TOSZ), undoped silicate glass (USG), spin-on glass (SOG), flowable oxide (FOx), tetraethyl orthosilicate (TEOS) or high-density plasma chemical vapor deposition (HDP-CVD) oxide, or the like or a combination thereof. The first insulating interlayer may be formed by a CVD process, a plasma-enhanced chemical vapor deposition (PE-CVD) process, an ALD process, a HDP-CVD process, or the like or a combination thereof.

The first insulating interlayer is partially etched to form a first insulating interlayer pattern 118 having a contact hole therethrough. The contact hole partially exposes the source/drain region 114. A first conductive layer is formed on the first insulating interlayer pattern 118 to fill up the contact hole.

The first conductive layer may include a metal, a metal nitride, or the like or a combination thereof. For example, the first conductive layer may include tungsten (W), aluminum (Al), titanium (Ti), tantalum (Ta), copper (Cu), tungsten nitride (WN), aluminum nitride (AlN), titanium nitride (TiN), tantalum nitride (TaN), titanium aluminum nitride (TiAlN), or the like. These may be used alone or in a combination thereof. The first conductive layer may be formed by a sputtering process, a CVD process, an ALD process, pulse laser deposition (PLD) process, or the like or a combination thereof.

An upper portion of the first conductive layer may be planarized by a chemical mechanical polishing (CMP) process, an etch back process or a combination of a CMP process and an etch back process until the first insulating interlayer pattern 118 is exposed.

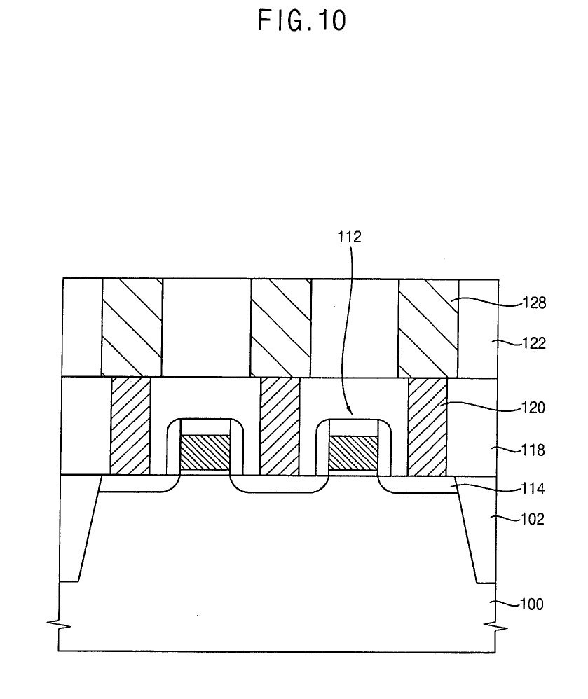

Thus, a contact plug 120 may be formed through the first insulating interlayer pattern 118. In one embodiment, the contact plug 120 may be used to connect the source/drain region 114 with a subsequently formed lower electrode 128 (see FIG. 10).

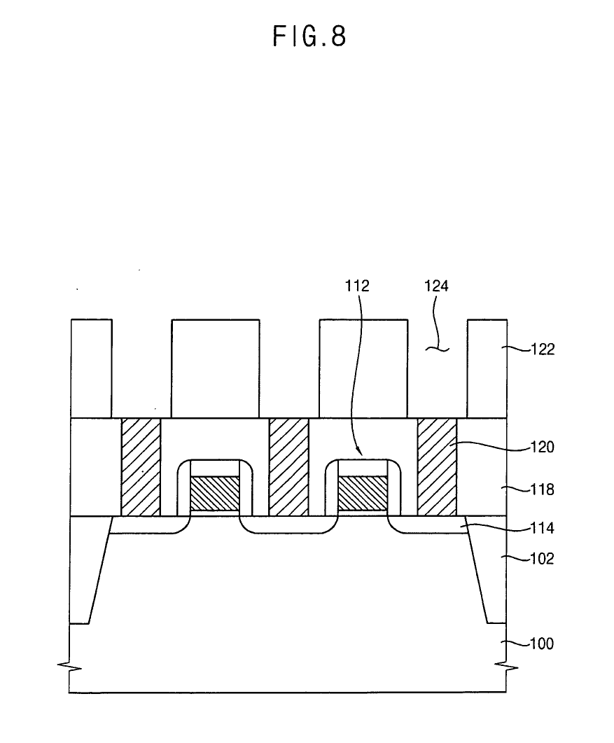

Referring to FIG. 8, a second insulating interlayer (not shown) is formed on the first insulating interlayer pattern 118 having the contact plug 120 therein. The second insulating interlayer may, for example, include BPSG, TOSZ, USG, SOG, FOX, TEOS HDP-CVD oxide, or the like or a combination thereof. In an example embodiment, the second insulating interlayer is formed using a material substantially the same as that of the first insulating interlayer. In another embodiment, the second insulating interlayer may be formed using a material different from that of the first insulating interlayer.

The second insulating interlayer is partially etched to form a second insulating interlayer pattern 122 having an opening 124 therethrough, which exposes the contact plug 120.

In one embodiment, the second insulating interlayer pattern 122 may be formed by forming an organic anti-reflective coating (ARC) layer (not shown) on the second insulating interlayer and, subsequently, forming a photoresist film (not shown) formed on the organic ARC layer. The organic ARC layer prevents back reflection from the second insulating interlayer while the photoresist film is patterned to form a photoresist pattern, and thus a sidewall of the photoresist pattern may have a good vertical profile. For example, the organic ARC layer may be formed using amorphous carbon or amorphous silicon.

The organic ARC layer and the second insulating interlayer are then sequentially etched using the photoresist pattern as an etching mask to form an organic ARC layer pattern (not shown) and the second insulating interlayer pattern 122 having the opening 124 exposing the contact plug 120.

The organic ARC layer pattern and the photoresist pattern may then be removed by an ashing process and/or a stripping process.

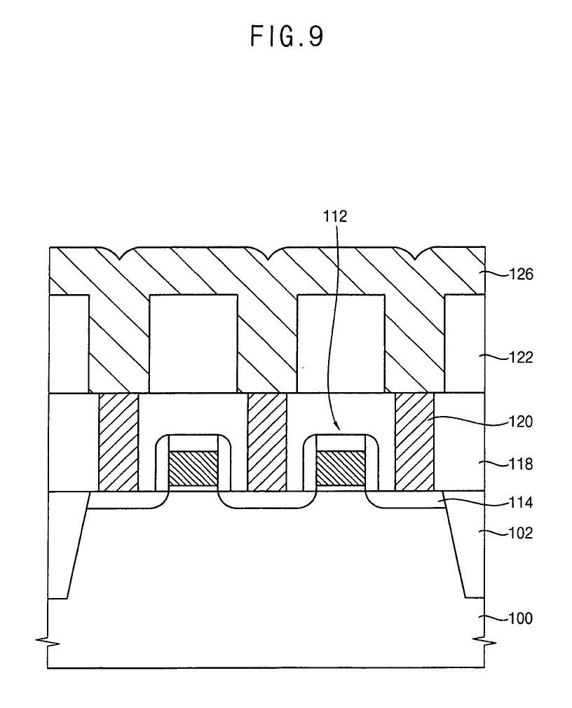

Referring to FIG. 9, a second conductive layer 126 is formed on the second insulating interlayer pattern 122 to fill up the opening 124. In one embodiment, the second conductive layer 126 includes titanium aluminum nitride. In another embodiment, the second conductive layer 126 may be formed as a titanium aluminum nitride layer.

A method of forming the titanium aluminum nitride is substantially the same as the method illustrated with reference to FIGS. 3 to 4, and thus, the method is simply described below.

A first source and a second source are reacted with each other to form a first reactant, the first reactant is reacted with a third source to form a second reactant, and the second reactant is reacted with a fourth source to form the titanium aluminum nitride layer.

The first reactant is formed at a temperature of about 400° C. to about 600° C. under a pressure of about 0.7 Torr to about 5.0 Torr, so that binding sites may be formed in the first reactant. Aluminum included in the third source is bound to the binding sites, so that the titanium aluminum nitride layer may have a good step coverage. More detail explanations on this aspect will be provided later.

Referring to FIG. 10, an upper portion of the second conductive layer 126 is planarized until the second insulating interlayer pattern 122 is exposed.

The upper portion of the second conductive layer 126 may be planarized by a CMP process, an etch back process or a combination of a CMP process and an etch back process.

The lower electrode 128 may be formed from the second conductive layer 126 by the planarization process.

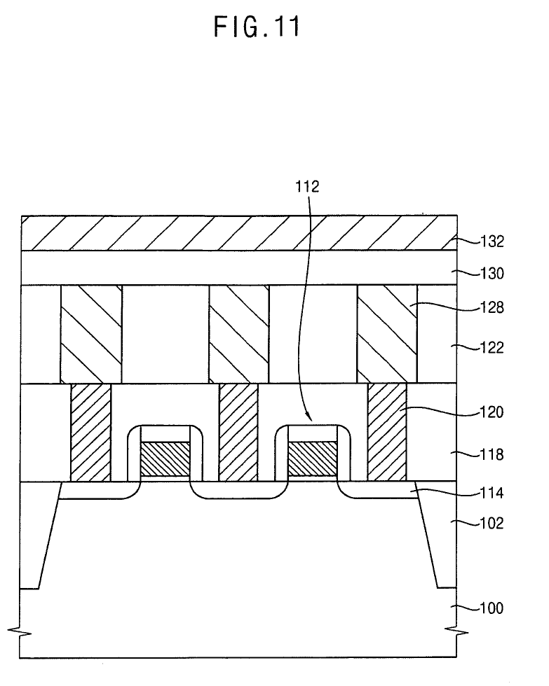

Referring to FIG. 11, a phase-change material layer 130 is formed on the lower electrode 128 and the second insulating interlayer pattern 122.

The phase-change material layer 130 may, for example, include a chalcogenide or chalcogen alloy. For example, the phase-change material layer 130 may include germanium-antimony-tellurium (Ge—Sb—Te), arsenic-antimony-tellurium (As—Sb—Te), tin-antimony-tellurium (Sn—Sb—Te), tin-indium-antimony-tellurium (Sn—In—Sb—Te), arsenic-germanium-antimony-tellurium (As—Ge—Sb—Te) or the like or a combination thereof. In another embodiment, the phase-change material layer 130 may include an alloy formed of antimony, tellurium and a Group 5B element (e.g., tantalum-antimony-tellurium (Ta—Sb—Te), niobium-antimony-tellurium (Nb—Sb—Te) or vanadium-antimony-tellurium (V—Sb—Te), or an element in Group 5B-antimony-selenium such as tantalum-antimony-selenium (Ta—Sb—Se), niobium-antimony-selenium (Nb—Sb—Se), vanadium-antimony-selenium (V—Sb—Se), or the like or a combination thereof). In another embodiment, the phase-change material layer 130 may include an alloy formed of antimony, tellurium and a Group 6B element (e.g., tungsten-antimony-tellurium (W—Sb—Te), molybdenum-antimony-tellurium (Mo—Sb—Te), chromium-antimony-tellurium (Cr—Sb—Te), or the like or a combination thereof). In another embodiment, the phase-change material layer 130 may include an alloy formed of antimony, selenium and Group 6B element (e.g., tungsten-antimony-selenium (W—Sb—Se), molybdenum-antimony-selenium (Mo—Sb—Se), chromium-antimony-selenium (Cr—Sb—Se), or the like or a combination thereof). The phase-change material layer 130 may be formed by a sputtering process, a PLD process, an ALD process, a CVD process or the like or a combination thereof.

A third conductive layer 132 is formed on the phase-change material layer 130.

The third conductive layer 132 may, for example, include polysilicon doped with impurities, a metal, a metal silicide, a metal nitride, or the like. These may be used alone or in a combination thereof. For example, the third conductive layer 132 may include titanium nitride (TiN), tungsten nitride (WN), tantalum nitride (TaN), aluminum nitride (AlN), titanium aluminum nitride (TiAlN), tungsten (W), aluminum (Al), titanium silicide (TiSi) tantalum silicide (TaSi), or the like. These may be used alone or in a combination thereof.

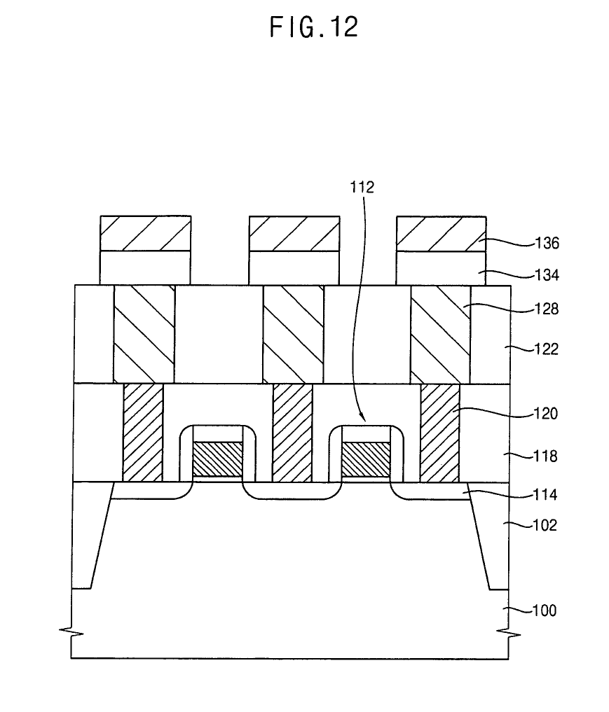

Referring to FIG. 12, the third conductive layer 132 and the phase-change material layer 130 are patterned (e.g., etched) to form an upper electrode 136 and a phase-change material layer pattern 134, respectively.

Thus, a phase-change memory device having the lower electrode 128, the phase-change material layer pattern 134 and the upper electrode 136 may be formed.

According to some example embodiments, a phase-change memory device may be formed to include a lower electrode 128 including titanium aluminum nitride formed according to the method exemplarily shown in FIGS. 3 and 4. Such a phase-change memory device, therefore, may have an improved throughput. Additionally, the specific resistance of the lower electrode 128 may be varied by controlling amounts of aluminum and nitrogen present in the lower electrode 128.

Hereinafter, characteristics of the titanium aluminum nitride layer formed by the above method and the phase-change memory device including the titanium aluminum nitride layer will be explained.

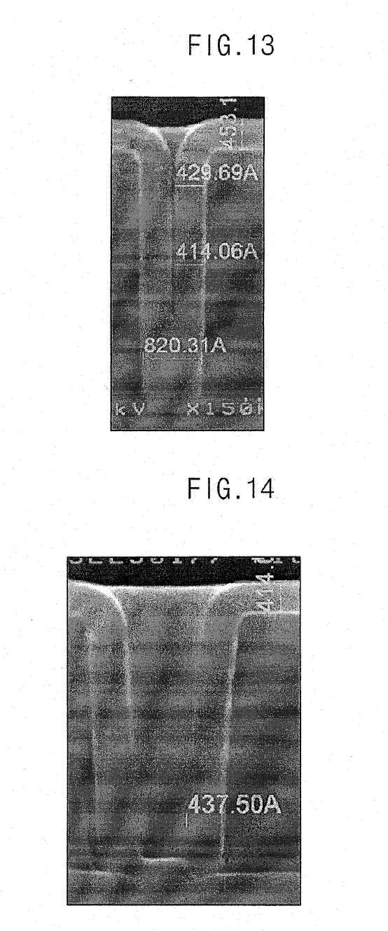

FIGS. 13 and 14 are SEM pictures illustrating step coverage characteristics of a titanium aluminum nitride layer formed in accordance with an example embodiment of the present invention. Specifically, FIG. 13 is a SEM picture illustrating a lower electrode in a cell region of a phase-change memory device, and FIG. 14 is a SEM picture illustrating the lower electrode in a peripheral region of the phase-change memory device.

The titanium aluminum nitride layer in FIGS. 13 and 14 has been formed by the method described with respect to FIGS. 3 and 4. The titanium aluminum nitride layer has a step coverage of about 91.6% in the cell region and about 98.4% in the peripheral region.

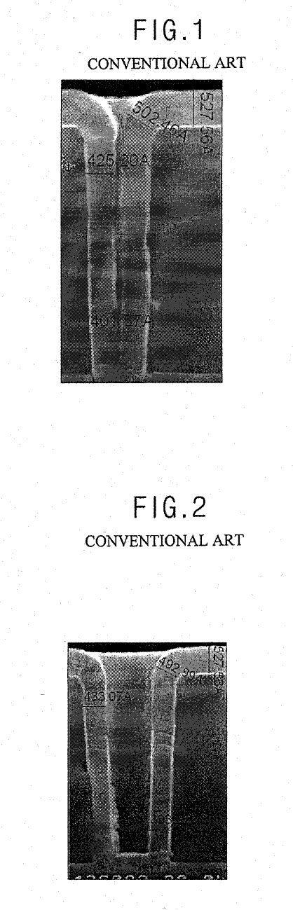

Meanwhile, and as mentioned above the titanium aluminum nitride layer in FIGS. 1 and 2 formed by a conventional method has a step coverage of about 75% in the cell region and about 77% in the peripheral region. Thus, the titanium aluminum nitride layer formed in accordance with the embodiments exemplarily described herein has step coverage that is superior to the titanium aluminum nitride layer formed by the conventional method.

In the method of forming the titanium aluminum nitride layer in accordance with an example embodiment of the present invention, a first source and a second source are reacted at a temperature of about 400° C. to about 600° C. under a pressure of about 0.7 Torr to about 5.0 Torr to form a first reactant, and the first reactant includes binding sites to which aluminum included in a third source is bound. Thus, the titanium aluminum nitride layer may have the good step coverage.

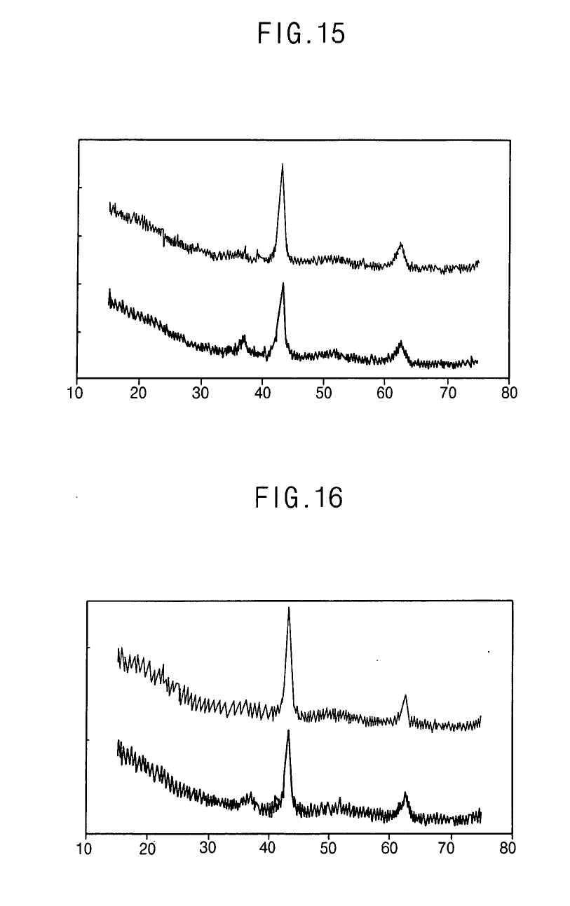

FIG. 15 is graphs showing X-ray diffraction (XRD) patterns of crystal structures of a titanium aluminum nitride layer formed by a conventional method and a titanium aluminum nitride layer in accordance with an example embodiment of the present invention, respectively. FIG. 16 is graphs showing XRD patterns of the crystal structures of the titanium aluminum nitride layers in FIG. 15 after performing heat treatments.

Referring to FIG. 15, the upper graph represents the crystal structure of the titanium aluminum nitride layer formed by the conventional ALD process whereas the lower graph represents the crystal structure of the titanium aluminum nitride layer formed in accordance with an example embodiment of the present invention. As shown in FIG. 15, the crystal structures of the two titanium aluminum nitride layers are very similar to each other.

Referring FIG. 16, the upper graph represents the crystal structure of the titanium aluminum nitride layer formed by the conventional ALD process and thermally treated at a temperature of about 700° C. whereas the lower graph represents the crystal structure of the titanium aluminum nitride layer formed in accordance with an example embodiment of the present invention and thermally treated at a temperature of about 700° C. As shown in FIG. 16, the crystal structures of the two titanium aluminum nitride layers are very similar each other.

In view of the crystal structures represented in FIGS. 15 and 16, the crystal structure of the titanium aluminum nitride layer formed by the conventional method is similar to that of the titanium aluminum nitride layer in accordance with an example embodiment of the present invention, and those are still similar to each other even after performing a heat treatment.

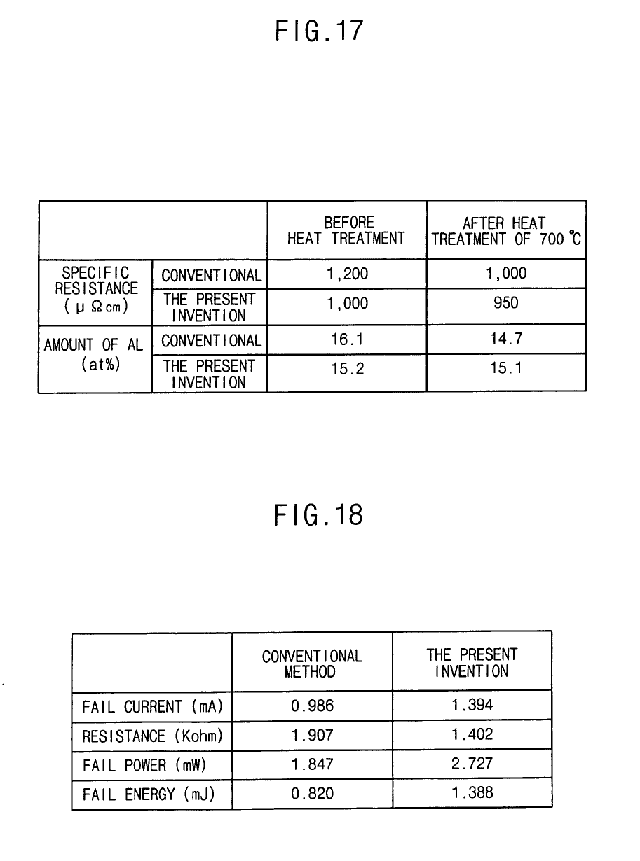

FIG. 17 is a table showing specific resistances and amounts of aluminum present in a titanium aluminum nitride layer formed by a conventional method and a titanium aluminum nitride layer in accordance with an example embodiment of the present invention, respectively, before and after performing heat treatments.

Referring to FIG. 17, a titanium aluminum nitride layer formed by a conventional method has a specific resistance of about 1,200 μΩ cm before performing a heat treatment at a temperature of about 700° C. and has a specific resistance of about 1,000 μΩ cm after performing the heat treatment at a temperature of about 700° C. Thus, the difference in specific resistances before and after performing the heat treatment was about 200 μΩ cm. Meanwhile, the titanium aluminum nitride layer formed in accordance with an example embodiment of the present invention had a specific resistance of about 1,000 μΩ cm before performing a heat treatment at a temperature of about 700° C. and had a specific resistance of about 950 μΩcm after performing the heat treatment at a temperature of about 700° C. Thus, the difference in specific resistances before and after performing the heat treatment was about 50 μΩ cm.

An amount of aluminum in the titanium aluminum nitride layer formed by the conventional method was about 16.1% by weight before the heat treatment at a temperature of about 700° C. and was about 14.75% by weight after the heat treatment at a temperature of about 700° C. Thus, the difference in the amount of aluminum content before and after the heat treatment was about 1.4% by weight. Meanwhile, an amount of aluminum in the titanium aluminum nitride layer in accordance with an example embodiment of the present invention was about 15.2% by weight before the heat treatment at a temperature of about 700° C. and was about 15.1% by weight after the heat treatment at a temperature of about 700° C. Thus, the difference in the amount of aluminum content before and after the heat treatment was about 0.1% by weight. Thus, the titanium aluminum nitride layer in accordance with an example embodiment of the present invention has a thermal durability superior to that of the titanium aluminum nitride layer formed by the conventional method.

FIG. 18 is a table showing currents, resistances, powers and energies associated with device failure of a titanium aluminum nitride layer formed by a conventional method and a titanium aluminum nitride layer formed in accordance with an example embodiment of the present invention, respectively.

Referring to FIG. 18, the current, resistance, power and energy associated with device failure of the titanium aluminum nitride layer formed by the conventional method was less than that of the titanium aluminum nitride layer formed in accordance with an example embodiment of the present invention.

Accordingly, operational failures occurring in the titanium aluminum nitride layer formed in accordance with an example embodiment of the present invention at a current higher than that of operational failures occurring in the titanium aluminum nitride layer formed by the conventional method. Additionally, operational failures occurring in the titanium aluminum nitride layer formed in accordance with an example embodiment of the present invention at a power higher than that of operational failures occurring in the titanium aluminum nitride layer formed by the conventional method. The results about the currents and the powers show that the titanium aluminum nitride layer formed in accordance with an example embodiment of the present invention has an electrical durability, which depends on the heat generation due to the currents or the power, which is greater than that of the titanium aluminum nitride layer formed by the conventional method.

According to some example embodiments, a titanium aluminum nitride layer having a good step coverage, a good thermal and electrical durability, and a desired thickness may be easily formed.

Thus, a phase-change memory device using the titanium aluminum nitride layer as a lower electrode may have good characteristics, and thus may have an improved throughput.

The following paragraphs describe some exemplary embodiments of the present invention. These embodiments are illustrative and non-limiting.

In a method of forming a titanium aluminum nitride layer, a first reactant is formed on a substrate by reacting a first source including titanium (Ti) and a second source including nitrogen (N₂). A second reactant is formed by providing a third source including aluminum (Al) onto the substrate having the first reactant thereon to react the third source with the first reactant. A third reactant is formed by providing a fourth source including nitrogen (N₂) onto the substrate having the second reactant thereon to react the fourth source with the second reactant.

In an example embodiment, the first reactant may be formed at a temperature of about 400° C. to about 600° C. under a pressure of about 0.7 Torr to about 5.0 Torr.

In an example embodiment, the second and third reactants may be formed at a temperature of about 400° C. to about 600° C. under a pressure of about 0.7 Torr to about 5.0 Torr.

In an example embodiment, the first source may be formed using titanium tetrachloride (TiCI₄) gas, the second and fourth sources are formed using ammonia (NH₃) gas, and the third source is formed using trimethylaluminum (TMA) gas.

In an example embodiment, the third source may be provided onto the substrate together with an inactive gas serving as a carrier gas.

In an example embodiment, the titanium aluminum nitride may have a structural formula of Ti₁₋ₓAlₓN, wherein x is more than 0 and less than 0.3.

In an example embodiment, a first purge gas may be further provided to remove portions of the first and second sources remaining on the substrate after forming the first reactant. A second purge gas may be further provided to remove a portion of the third source remaining on the substrate after forming the second reactant. A third purge gas may be further provided to remove a portion of the fourth source remaining on the substrate after forming the third reactant

In an example embodiment, forming the second reactant and forming the third reactant may be repeatedly performed.

In an example embodiment, a flow rate ratio of the first source to the second source may be in a range of about 1:25 to about 1:45.

In the method of manufacturing the phase-change memory device, an insulating pattern having an opening is formed therethrough on a substrate. A titanium aluminum nitride layer filling up the opening is formed as follows:

A first reactant is formed by reacting a first source including titanium (Ti) and a second source including nitrogen (N₂). A second reactant is formed by providing a third source including aluminum (Al) to react the third source with the first reactant.

A third reactant is formed by providing a fourth source including nitrogen (N₂) to react the fourth source with the second reactant.

An upper portion of the titanium aluminum nitride layer is removed until the insulating pattern is exposed to form a lower electrode. A phase-change material layer and an upper electrode are formed on the lower electrode.

In an example embodiment, the first reactant may be formed at a temperature of about 400° C. to about 600° C. under a pressure of about 0.7 Torr to about 5.0 Torr.

In an example embodiment, the titanium aluminum nitride layer may be formed at a temperature of about 400° C. to about 600° C. under a pressure of about 0.7 Torr to about 5.0 Torr. In an example embodiment, the first source may be formed using titanium tetrachloride (TiCI₄) gas, the second and fourth sources may be formed using NH₃ gas, and the third source may be formed using trimethylaluminum (TMA) gas.

In an example embodiment, the titanium aluminum nitride may have a structural formula of Ti₁₋ₓAlₓN, wherein x is more than 0 and less than 0.3.

In an example embodiment, the lower electrode may have a specific resistance of about 600 to about 2,000 μΩ cm.

According to the above, a process time may be decreased to improve throughput by reacting a first source and a second source to form a first reactant, providing a third source to the first reactant to form a second reactant, providing a fourth source to the second reactant to form a titanium aluminum nitride layer. Further, step coverage of the titanium aluminum nitride layer in accordance with the present invention is superior to that in accordance with a conventional method. Furthermore, contamination of a chamber may be reduced.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of forming a titanium aluminum nitride layer, comprising:
forming a first reactant on a substrate by reacting a first source including titanium and a second source including nitrogen;
forming a second reactant by providing a third source including aluminum onto the substrate having the first reactant thereon and reacting the third source with the first reactant; and
forming a third reactant by providing a fourth source including nitrogen onto the substrate having the second reactant thereon and reacting the fourth source with the second reactant.

2. The method of claim 1, wherein the first reactant is formed at a temperature of about 400° C. to about 600° C. under a pressure of about 0.7 Torr to about 5.0 Torr.

3. The method of claim 1, wherein the second and third reactants are formed at a temperature of about 400° C. to about 600° C. under a pressure of about 0.7 Torr to about 5.0 Torr.

4. The method of claim 1, wherein the first source includes titanium tetrachloride gas, the second and fourth sources include ammonia gas, and the third source includes trimethylaluminum gas.

5. The method of claim 1, wherein the third source is provided onto the substrate together with an inactive gas serving as a carrier gas.

6. The method of claim 1, wherein the titanium aluminum nitride has a structural formula of Ti₁₋ₓAlₓN, wherein x is more than 0 and less than 0.3.

7. The method of claim 1, further comprising:
after forming the first reactant, providing a first purge gas to remove portions of the first and second sources remaining on the substrate;
after forming the second reactant, providing a second purge gas to remove a portion of the third source remaining on the substrate; and
after forming the third reactant, providing a third purge gas to remove a portion of the fourth source remaining on the substrate.

8. The method of the claim 1, further comprising repeatedly forming the second reactant and forming the third reactant.

9. The method of claim 1, wherein a flow rate ratio of the first source to the second source is in a range of about 1:25 to about 1:45.

10. A method of manufacturing a phase-change memory device, comprising:
forming an insulating pattern having an opening therethrough on a substrate;
forming a titanium aluminum nitride layer filling up the opening according to a method comprising:
forming a first reactant by reacting a first source including titanium and a second source including nitrogen;
forming a second reactant by providing a third source including aluminum and reacting the third source with the first reactant; and
forming a third reactant by providing a fourth source including nitrogen and
reacting the fourth source with the second reactant;
removing an upper portion of the titanium aluminum nitride layer until the insulating pattern is exposed to form a lower electrode; and
forming a phase-change material layer and an upper electrode on the lower electrode.

11. The method of claim 10, wherein the first reactant is formed at a temperature of about 400° C. to about 600° C. under a pressure of about 0.7 Torr to about 5.0 Torr.

12. The method of claim 10, wherein the titanium aluminum nitride layer is formed at a temperature of about 400° C. to about 600° C. under a pressure of about 0.7 Torr to about 5.0 Torr.

13. The method of claim 10, wherein the first source includes titanium tetrachloride gas, the second and fourth sources include ammonia gas, and the third source includes trimethylaluminum gas.

14. The method of claim 10, wherein the titanium aluminum nitride has a structural formula of Ti₁₋ₓAlₓN, wherein x is more than 0 and less than about 0.3.

15. The method of claim 10, wherein the lower electrode has a specific resistance of about 600 μΩ cm to about 2,000 μΩ cm.
